(19) United States
(12) Patent Application Publication
(10) Pub. No.: US 2026/0104457 A1
(43) Pub. Date: Apr. 16, 2026

(54) Health Condition Assessment Method And Apparatus For Medium/Low Voltage Switchgear

(71) Applicant: Siemens Ltd., China, Beijing (CN)

(72) Inventors: Jing Li, Beijing (CN); Shuang Zhao, Beijing (CN); Wen Tao Hua, Beijing (CN); Hao Liu, Beijing (CN); Peng Fei Zhang, Beijing (CN); Jens Weibert, Shanghai (CN); Zhao Yan Guo, Shanghai (CN)

(73) Assignee: Siemens Ltd., China, Beijing (CN)

(21) Appl. No.: 19/115,297

(22) PCT Filed: Sep. 27, 2023
(86) PCT No.: PCT/CN2023/122283

§ 371 Date: Mar. 26, 2025

(30) Foreign Application Priority Data
Sep. 27, 2022 (CN) 202211181124.5

(51) Int. Cl. G01R 31/327

(52) U.S. Cl. CPC G01R 31/3277

(57) ABSTRACT

An example health condition assessment method for a medium/low voltage switchgear having temperature sensors at connection points between components of the switchgear, and a main conduction circuit includes: determining key connection points in the conduction circuit to serve as virtual temperature measurement points according to a main conduction circuit structure of the switchgear; establishing a temperature analysis model of the main conduction circuit according to the distribution of the measurement points; obtaining a current value, an environment temperature value, and temperature values of the main conduction circuit sensed by the temperature sensors, and putting them into the temperature analysis model to obtain temperature values or temperature-rise values of the measurement points in the circuit; and obtaining limit values of the virtual temperature measurement points in the main conduction circuit using the values to normalize the values, and assessing the health condition of the switchgear according to the values.

### CROSS-REFERENCE TO RELATED APPLICATIONS

This application is a U.S. National Stage Application of International Application No. PCT/CN2023/122283 filed Sep. 27, 2023, which designates the United States of America, and claims priority to CN Application No. 202211181124.5 filed Sep. 27, 2022, the contents of which are hereby incorporated by reference in their entirety.

### TECHNICAL FIELD

The present disclosure mainly relates electricity. Various embodiments of the teachings herein include health condition assessment methods and/or apparatus for a medium/low voltage switchgear.

### BACKGROUND

A medium/low voltage switchgear is a key device for the operation of a power distribution system; it is a core apparatus for ensuring a power supply/distribution system operates safely and reliably. A medium/low voltage switchgear comprises a main conduction circuit and temperature sensors arranged on connection points of components, temperature data collected by means of the temperature sensors and corresponding temperature data is acquired by means of communication technology, and, in conjunction with a corresponding temperature rise analysis model, state monitoring and operating state assessment of the main conduction circuit of the switchgear can be realized. However, taking into account design requirements for high reliability of a medium voltage switchgear, the number of temperature measurement sensors for the main conduction circuit should be as small as possible, so as to reduce the influence of the sensors on device reliability to the greatest extent. Also, the sensors do not all perform measurement in direct contact with the conduction circuit.

Therefore, realizing accurate temperature-rise state analysis and assessment of a main conduction circuit, by means of measurement with a limited number of temperature sensors, has always been a challenging technical difficulty faced by medium voltage switch manufacturers. In addition, with regard to judging the health state of a main conduction circuit on the basis of monitoring a temperature or temperature rise, a simple judgment is merely performed, which depends on one parameter, namely a temperature limit value of a temperature measurement point. That is, for a measured temperature exceeding the temperature limit value, the judgment is an abnormal warning. However, as the complexity of power distribution systems increases, the operation of medium/low voltage switchgears will also become more complex, and a judgment method which merely depends on a conventional single threshold value is very limited.

In order to increase accuracy, the prior art uses a 3D heat network simulation model method to assess the healthy operating state of a main conduction circuit of a medium/low voltage switchgear. The 3D heat network simulation model is a heat network model which establishes a switch on the basis of a finite element analysis method, wherein temperature analysis is performed by means of numerical simulation, and, by means of comparison of temperature limit values of key points of an entire conduction circuit, using colors to represent temperature levels, whether a temperature requirement has been exceeded may be distinguished by means of the colors. However, a 3D heat network simulation model is a common method used in an offline simulation environment, the computational analysis time is long, and it is not suitable for engineering implementation, that is, not suitable for switch temperature-rise monitoring and analysis online.

### SUMMARY

To engage the above technical problems, the present disclosure describes health condition assessment methods and apparatus for a medium/low voltage switchgear, so as to accurately display the health condition of a main conduction circuit in a medium/low voltage switchgear in real time. For example, some embodiments of the teachings herein include a 1. A health condition assessment method (100) for a medium/low voltage switchgear, connection points between components of the medium/low voltage switchgear being provided with temperature sensors, and a main conduction circuit being provided within the components, wherein the assessment method (100) comprises: according to a main conduction circuit structure of the medium/low voltage switchgear, determining key connection points in the main conduction circuit to serve as virtual temperature measurement points (110); according to the distribution of the virtual temperature measurement points, establishing a temperature analysis model of the main conduction circuit (120); obtaining a current value, an environment temperature value, and temperature values which are sensed by the temperature sensors, of the main conduction circuit, and inputting the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit (130); and obtaining temperature limit values or temperature-rise limit values of the virtual temperature measurement points in the main conduction circuit, using the temperature limit values or temperature-rise limit values to normalize the temperature values or temperature-rise values, and assessing the health condition of the medium/low voltage switchgear according to the normalized temperature values or temperature-rise values (140).

In some embodiments, assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels.

In some embodiments, the method (100) further comprises: displaying a normalized temperature curve formed by the temperature value or temperature-rise value of each virtual temperature measurement point after normalization, and displaying a level line of each of the multiple health risk levels.

In some embodiments, establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit.

In some embodiments, obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear.

As another example, some embodiments include a health condition assessment apparatus (300) for a medium/low voltage switchgear, connection points between components of the medium/low voltage switchgear being provided with temperature sensors, and a main conduction circuit being provided within the components, wherein the assessment apparatus (300) comprises: a determination module (310), which determines key connection points in the main conduction circuit to serve as virtual temperature measurement points, according to a main conduction circuit structure of the medium/low voltage switchgear; a modelling module (320), which establishes a temperature analysis model of the main conduction circuit, according to the distribution of the virtual temperature measurement points; an application module (330), which obtains a current value, an environment temperature value, and temperature values which are sensed by the temperature sensors, of the main conduction circuit, and inputs the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit; and an assessment module (340), which obtains temperature limit values or temperature-rise limit values of the virtual temperature measurement points in the main conduction circuit, uses the temperature limit values or temperature-rise limit values to normalize the temperature values or temperature-rise values, and assesses the health condition of the medium/low voltage switchgear according to the normalized temperature values or temperature-rise values.

In some embodiments, the assessment module (340) assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels.

In some embodiments, the apparatus (300) further comprises: displaying a normalized temperature curve formed by the temperature value or temperature-rise value of each virtual temperature measurement point after normalization, and displaying a level line of each of the multiple health risk levels.

In some embodiments, the modelling module (320) establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit.

In some embodiments, the assessment module (340) obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear.

As another example, some embodiments of the teachings herein include an electronic device (400) comprising a processor (410), a memory (420) and an instruction stored on the memory (420), wherein one or more of the methods described herein is implemented when the instruction is executed by the processor (410).

As another example, some embodiments of the teachings herein include a computer-readable storage medium on which a computer instruction is stored, one or more of the methods as described herein implemented when the computer instruction is run.

As another example, some embodiments include a computer program product, wherein the computer program product comprises a computer program, and, when executed by a processor, the computer program implements one or more of the methods as described herein.

### BRIEF DESCRIPTION OF THE DRAWINGS

The accompanying drawings below are merely intended to illustrate and explain the present disclosure schematically, without limiting the scope thereof, where:

FIG. 1 shows a flowchart of an example health condition assessment method incorporating teachings of the present disclosure;

FIGS. 2A and 2B show schematic diagrams of normalized temperature value curves incorporating teachings of the present disclosure;

FIG. 3 shows a schematic diagram of an example health condition assessment apparatus incorporating teachings of the present disclosure; and

FIG. 4 shows a schematic diagram of an example electronic device incorporating teachings of the present disclosure.

### KEY TO LABELS USED IN THE DRAWINGS

100 health condition assessment method
110-140 steps
300 health condition assessment apparatus
310 determination module
320 modelling module
330 application module
340 assessment module
400 electronic device
410 processor
420 memory

### DETAILED DESCRIPTION

Some embodiments of the teachings herein include a health condition assessment method for a medium/low voltage switchgear, temperature sensors are provided at connection points between components of the medium/low voltage switchgear, a main conduction circuit is provided within the components, and the assessment method comprises: according to a main conduction circuit structure of the medium/low voltage switchgear, determining key connection points in the main conduction circuit to serve as virtual temperature measurement points; according to the distribution of the virtual temperature measurement points, establishing a temperature analysis model of the main conduction circuit; obtaining a current value, an environment temperature value, and temperature values which are sensed by the temperature sensors, of the main conduction circuit, and inputting the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit; and obtaining temperature limit values or temperature-rise limit values of the virtual temperature measurement points in the main conduction circuit, using the temperature limit values or temperature-rise limit values to normalize the temperature values or temperature-rise values, and assessing the health condition of the medium/low voltage switchgear according to the normalized temperature values or temperature-rise values. Thus, by means of establishing an online temperature analysis model, real-time performance is provided, and matching is possible with the current main conduction circuit and the distribution of virtual temperature measurement points thereof, improving the accuracy of health condition assessment, and temperature limit values/temperature-rise limit values are used for normalizing temperature values/temperature-rise values output by the temperature analysis model, and the health condition of a medium/low voltage switchgear is assessed according to the normalized temperature values or temperature-rise values, further improving the accuracy of the health condition assessment.

In some embodiments, assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels. Thus, by means of defining multiple health risk levels, graded assessment of the operating condition of the medium/low voltage switchgear is realized, such that the assessment results are more precise.

In some embodiments, the method further comprises: displaying a normalized temperature curve formed by the temperature value or temperature-rise value of each virtual temperature measurement point after normalization, and displaying a level line of each of the multiple health risk levels. Thus, by means of displaying a normalized temperature curve formed by the temperature value or temperature-rise value of each virtual temperature measurement point after normalization, and displaying a level line of each of the multiple health risk levels, a user may see the health condition of each virtual temperature measurement point of the main conduction circuit in a visually direct way.

In some embodiments, establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit. Thus, a temperature analysis model of the main conduction circuit is established.

In some embodiments, obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear. Thus, the temperature limit values or temperature-rise limit values are matched with the type of the medium/low voltage switchgear, improving the accuracy of the health condition assessment.

Some embodiments include a health condition assessment apparatus for a medium/low voltage switchgear, temperature sensors being provided at connection points between components of the medium/low voltage switchgear, a main conduction circuit being provided within the components, and the assessment apparatus comprising: a determination module, which, according to a main conduction circuit structure of the medium/low voltage switchgear, determines key connection points in the main conduction circuit to serve as virtual temperature measurement points; a modelling module, which establishes a temperature analysis model of the main conduction circuit, according to the distribution of the virtual temperature measurement points; an application module, which obtains a current value, an environment temperature value, and temperature values which are sensed by the temperature sensors, of the main conduction circuit, and inputs the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit; and an assessment module, which obtains temperature limit values or temperature-rise limit values of the virtual temperature measurement points in the main conduction circuit, uses the temperature limit values or temperature-rise limit values to normalize the temperature values or temperature rise values, and assesses the health condition of the medium/low voltage switchgear according to the normalized temperature values or temperature-rise values.

In some embodiments, the assessment module assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels.

In some embodiments, the apparatus further comprises: displaying a normalized temperature curve formed by the temperature value or temperature-rise value of each virtual temperature measurement point after normalization, and displaying a level line of each of the multiple health risk levels.

In some embodiments, the modelling module establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit.

In some embodiments, the assessment module obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear.

Some embodiments include an electronic device comprising a processor, a memory and an instruction stored in the memory, wherein one or more of the methods described herein is implemented when the instruction is executed by the processor.

Some embodiments include a computer-readable storage medium on which a computer instruction is stored, one or more of the methods described herein executed when the computer instruction is run.

Some embodiments include a computer program product, wherein the computer program product comprises a computer program, and, when executed by a processor, the computer program executes one or more of the methods described herein.

To enable clearer understanding of the technical features, objectives, and effects of the teachings of the present disclosure, particular embodiments are now explained with reference to the accompanying drawings. Many specific details are expounded in the description below to facilitate full understanding, but the teachings may also be implemented in other ways different from those described here, so the scope of the present disclosure is not limited by the particular embodiments disclosed below.

As described in the application and the claims, unless exceptions are clearly indicated by the context, words such as “one”, “one piece”, “one type”, and/or “this” do not specifically refer to the singular but may also include the plural. Generally, the terms “comprising” and “containing” only indicate that the steps and elements clearly identified are included, but these steps and elements do not constitute an exclusive listing. The method or device may also contain other steps or elements.

Some embodiments include a health condition assessment method for a medium/low voltage switchgear; a medium voltage switchgear is a key device for the operation of a power distribution system, a main conduction circuit is an important constituent of a medium/voltage switchgear, and, in order to ensure the entire power distribution system operates safely and reliably, it is necessary to monitor and assess the operating state of the main conduction circuit of the medium/low voltage switchgear. Temperature sensors are provided at connection points between some limited components of the medium/low voltage switchgear, and the main conduction circuit is provided within the components, that is, the temperature sensors come into indirect contact with the main conduction circuit.

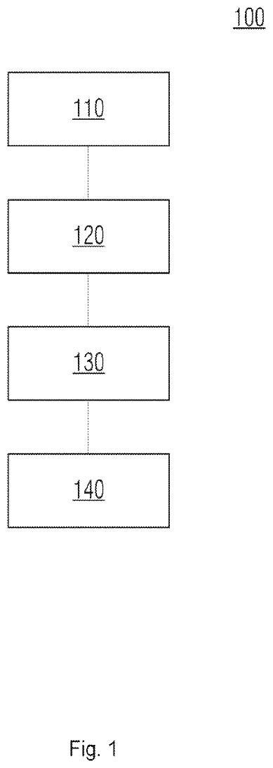

FIG. 1 is a flowchart of an example health condition assessment method 100 incorporating teachings of the present disclosure. As shown in FIG. 1, the assessment method 100 comprises:
Step 110, according to a main conduction circuit structure of the medium/low voltage switchgear, determining key connection points in the main conduction circuit to serve as virtual temperature measurement points. According to the main conduction circuit structure of the medium/low voltage switchgear, that is, component constituents of the main conduction circuit, key connection points in the main conduction circuit are determined to serve as virtual temperature measurement points, the positions and number of the virtual temperature measurement points in the main conduction circuit may be defined by a user, or the virtual temperature measurement points in the main conduction circuit may be automatically recommended by a system, or a user may adjust the positions and number of virtual temperature measurement points recommended by a system.

In some embodiments, the virtual temperature measurement point does not perform direct temperature measurement at this point, but rather represents the temperature situation at this point in the main conduction circuit by means of a temperature value obtained by an indirect means, such as model computation. It can be understood that, taking into account the structure of a main conduction circuit, generally multiple key connection points serve as virtual temperature measurement points; for example, in a main conduction circuit, 16 key connection points are determined to serve as virtual temperature measurement points.
Step 120, establishing a temperature analysis model of the main conduction circuit, according to the distribution of the virtual temperature measurement points. The distribution of the virtual temperature measurement points may be the number and positions of the virtual temperature measurement points, and changes in the main conduction circuit structure and the distribution of the virtual temperature measurement points will result in a change to the temperature analysis model. Therefore, a temperature analysis model of a corresponding main conduction circuit is established according to the distribution of the virtual temperature measurement points, and the temperature analysis model is online, performs in real time, and can match the current main conduction circuit and the distribution of the virtual temperature measurement points thereof. In some embodiments, the temperature analysis model of the main conduction circuit may be a data model, an equivalent-parameter heat analysis model, or a heat-dissipation analysis model of another form, etc.

In some embodiments, establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit. Specifically, an equivalent-parameter heat analysis model may be represented as T=f(I, Pₕₑₐₜ, R_{i, cont}, R_{i, cvt}, R_{i, cdt}), wherein T represents a temperature rise produced by a current, f represents the equivalent-parameter heat analysis model, I represents a current, Pₕₑₐₜ represents a heat loss produced by a current, R_{i, cont} represents a thermal contact resistance of a virtual temperature measurement point at the ith position, R_{i, cvt} represents convection thermal resistance of a virtual temperature measurement point at the ith position, and R_{i, cdt} represents conduction thermal resistance of a virtual temperature measurement point at the ith position, and the current I, heat loss of Pₕₑₐₜ, thermal Contact resistance of R_{i, cont}, convection thermal resistance of R_{i, cvt} and conduction thermal resistance of R_{i, cdt} are related to the structure of a main conduction circuit, and are related to other factors such as environment temperature, etc.
Step 130, obtaining a current value, an environment temperature value, and temperature values which are sensed by the temperature sensors, of the main conduction circuit, and inputting the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit.

A current value of the main conduction circuit may be obtained by means of an ammeter on the main conduction circuit, an environment temperature value may be obtained by means of an environment temperature sensor, actual temperature values are sensed by temperature sensors arranged between components of the medium/low voltage switchgear, the current value, the environment temperature value, and the temperature values which are sensed by the temperature sensors, of the main conduction circuit, are input into the temperature analysis model, of the main conduction circuit, established in step 120, and the temperature analysis model outputs temperature values or temperature-rise values of the virtual temperature measurement points in the main conduction circuit, according to the input current value, environment temperature value, and temperature values which are sensed by the temperature sensors, of the main conduction circuit.
Step 140, obtaining temperature limit values or temperature-rise limit values of the virtual temperature measurement points in the main conduction circuit, using the temperature limit values or temperature-rise limit values to normalize the temperature values or temperature-rise values, and assessing the health condition of the medium/low voltage switchgear according to the normalized temperature values or temperature-rise values. Limit values for temperature/temperature rise for key connection points in a medium/low voltage switchgear main conduction circuit may be provided in advance according to industry standard requirements; for example, a bus connection point has a maximum allowed temperature of 115° C./a maximum allowed temperature rise of 75° C., etc. After a temperature limit value or temperature-rise limit value of a virtual temperature measurement point in the main conduction circuit is obtained, a temperature value or temperature-rise value is normalized using the temperature limit value or temperature-rise limit value, and generally temperature limit values are used to normalize temperature values, that is, the temperature value is divided by the temperature limit value; for example, a temperature analysis model outputs a temperature value of a certain virtual temperature measurement point of 75° C., and a bus connection point has a maximum allowed temperature of 115° C./a maximum allowed temperature-rise of 75° C., hence the temperature value is normalized to be 75° C./115° C.=0.652. Thus, by means of establishing an online temperature analysis model, real-time performance is provided, and matching is possible with the current main conduction circuit and the distribution of virtual temperature measurement points thereof, improving the accuracy of health condition assessment, and temperature limit values/temperature-rise limit values are used for normalizing temperature values/temperature-rise values output by the temperature analysis model, and the health condition of a medium/low voltage switchgear is assessed according to the normalized temperature values or temperature-rise values, further improving the accuracy of the health condition assessment.

In some embodiments, assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels. For example, three health risk levels may be defined, respectively being healthy, at risk and high risk, wherein healthy, at risk and high risk are all provided with respective value intervals, the value intervals may be defined by a user, and the health risk level corresponding to the range of values into which the normalized temperature value or temperature-rise value falls is the health condition assessment result of the medium/low voltage switchgear. Thus, by means of defining multiple health risk levels, graded assessment of the operating condition of the medium/low voltage switchgear is realized, such that the assessment results are more precise.

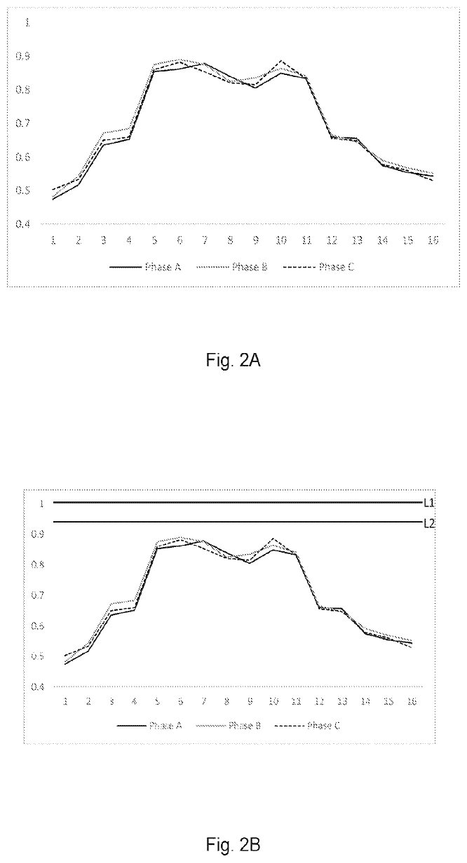

In some embodiments, the method further comprises: displaying a normalized temperature curve formed by the temperature value or temperature-rise value of each virtual temperature measurement point after normalization, and displaying a level line of each of the multiple health risk levels. FIGS. 2A and 2B are schematic diagrams of normalized temperature value curves according to an embodiment of the present invention. The horizontal coordinates of FIG. 2A are sequence numbers of virtual temperature measurement points, the vertical coordinates are normalized values, the three curves respectively represent three phases ABC, and normalized values of the temperatures of various virtual temperature measurement points can be seen in FIG. 2A. Level lines L1 and L2 are added in FIG. 2B, the level lines L1 and L2 may be defined by a user, below L2 (less than 0.9) represents healthy, between L2 and L1 (0.9 to 1) represents at risk, and above L1 (greater than or equal to 1) represents high risk. In FIG. 2B, the normalized curves are all below L2, representing the temperatures of all the virtual temperature measurement points of the main conduction circuit being normal, that is, the operating condition of the main conduction circuit is healthy. Thus, by means of displaying a normalized temperature curve formed by a temperature value or temperature-rise value of each virtual temperature measurement point after normalization, and displaying a level line of each of the multiple health risk levels, a user may see the health condition of each virtual temperature measurement point of the main conduction circuit in a visually direct way.

In some embodiments, obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear. Thus, the temperature limit values or temperature-rise limit values are matched with the type of the middle/low voltage switchgear, improving the accuracy of the health condition assessment.

Some embodiments include a health condition assessment method for a medium/low voltage switchgear, wherein by means of establishing an online temperature analysis model, real-time performance is provided, and matching is possible with the current main conduction circuit and the distribution of virtual temperature measurement points thereof, improving the accuracy of health condition assessment, and temperature limit values/temperature-rise limit values are used for normalizing temperature values/temperature-rise values output by the temperature analysis model, and the health condition of a medium/low voltage switchgear is assessed according to the normalized temperature values or temperature-rise values, further improving the accuracy of the health condition assessment.

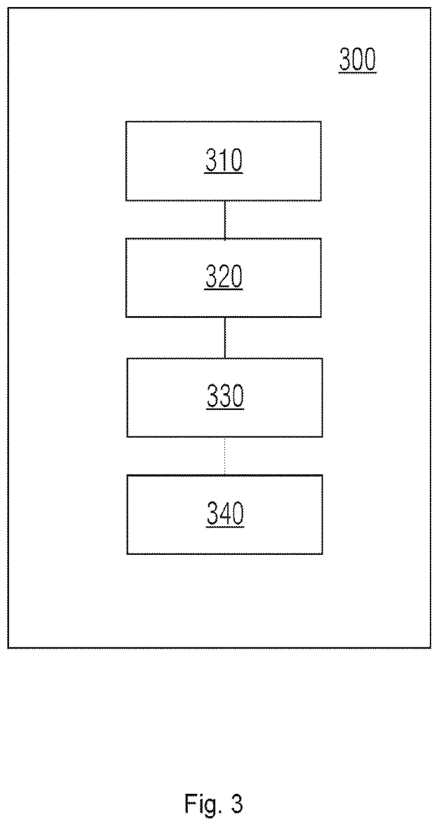

Some embodiments include a health condition assessment apparatus for a medium/low voltage switchgear, connection points between components of the medium/low voltage switchgear being provided with temperature sensors, and a main conduction circuit being arranged within the components. FIG. 3 is a schematic diagram of an example health condition assessment apparatus 300 incorporating teachings of the present disclosure.

As shown in FIG. 3, the assessment apparatus 300 comprises: a determination module 310, which determines key connection points in the main conduction circuit to serve as virtual temperature measurement points, according to a main conduction circuit structure of the medium/low voltage switchgear; a modelling module 320, which establishes a temperature analysis model of the main conduction circuit, according to the distribution of the virtual temperature measurement points; an application module 330, which obtains a current value, an environment temperature value, and temperature values which are sensed by the temperature sensors, of the main conduction circuit, and inputs the current value, the environment temperature value, and the temperature values which are sensed by the temperature sensors, of the main conduction circuit, into the temperature analysis model, so as to obtain temperature values or temperature-rise values of the virtual temperature measurement points in the main conduction circuit; and an assessment module 340, which obtains temperature limit values or temperature-rise limit values of the virtual temperature measurement points in the main conduction circuit, uses the temperature limit values or temperature-rise limit values to normalize the temperature values or temperature-rise values, and assesses the health condition of the medium/low voltage switchgear according to the normalized temperature values or temperature-rise values.

In some embodiments, the assessment module assessing the health condition of the medium/low voltage switchgear according to the normalized temperature values or temperature-rise values comprises: defining multiple health risk levels, and assessing the health condition of the medium/low voltage switchgear according to the normalized temperature values or temperature-rise values, and the multiple health risk levels.

In some embodiments, the apparatus further comprises: displaying a normalized temperature curve formed by the temperature value or temperature-rise value of each virtual temperature measurement point after normalization, and displaying a level line of each of the multiple health risk levels.

In some embodiments, the modelling module establishing a temperature analysis model of the main conduction circuit, according to the distribution of the virtual temperature measurement points, comprises: according to the number and positions of the virtual temperature measurement points, establishing a heat analysis model, based on equivalent parameters, of the main conduction circuit.

In some embodiments, the assessment module obtaining the temperature limit values or temperature-rise limit values of the virtual temperature measurement points in the main conduction circuit comprises: determining the type of the medium/low voltage switchgear, and determining the temperature limit values or temperature-rise limit values of the virtual temperature measurement points in the main conduction circuit according to the type of the medium/low voltage switchgear.

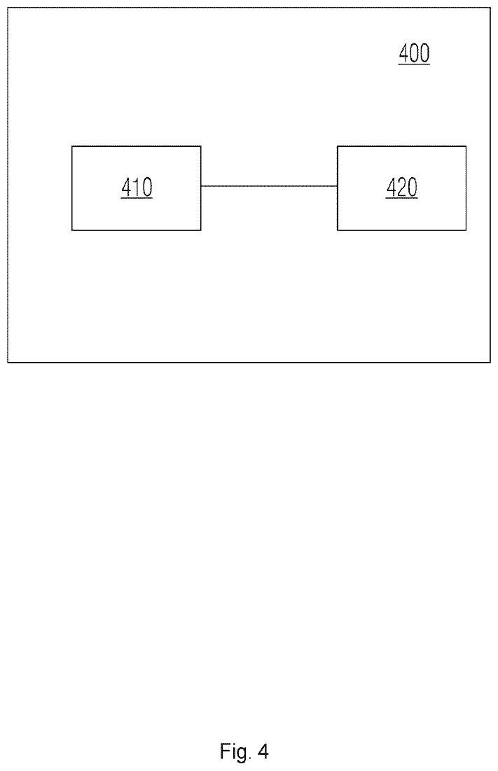

Some embodiments include an electronic device. FIG. 4 shows a schematic diagram of an example electronic device 400 incorporating teachings of the present disclosure. As shown in FIG. 4, the electronic device 400 comprises a processor 410 and a memory 420, wherein the memory 420 stores an instruction, and the method 100 described above is implemented when the instruction is executed by the processor 410.

Some embodiments include a computer-readable storage medium on which a computer instruction is stored, one or more of the methods described herein being executed when the computer instruction is run.

Some embodiments include a computer program product comprising a computer program, one or more of the methods described herein being implemented when the computer program is executed by a processor.

Some aspects of the method and apparatus described herein may be implemented wholly by hardware, wholly by software (including firmware, resident software, microcode, etc.), or by a combination of hardware and software. All of the above hardware or software may be referred to as a “data block”, “module”, “engine”, “unit”, “component” or “system”. The processor may be one or more application-specific integrated circuit (ASIC), digital signal processor (DSP), digital signal processing device (DAPD), programmable logic device (PLD), field programmable gate array (FPGA), processor, controller, microcontroller, microprocessor or a combination thereof. In addition, the various aspects might be manifested as a computer product located in one or more computer readable medium, the product comprising computer readable program code. For example, computer readable media may comprise, but are not limited to, magnetic storage devices (e.g. hard disks, floppy disks, magnetic tapes . . . ), optical disks (e.g. compact disks (CD), digital versatile disks (DVD) . . . ), smart cards and flash memory devices (e.g. cards, sticks, key drives . . . ).

A flow chart has been used here to explain the operations performed in the method according to an example embodiment. It should be understood that the abovementioned operations are not necessarily performed precisely in order. On the contrary, the various steps may be processed in reverse order or simultaneously. Moreover, other operations may be added to these processes, or one or more operation steps may be removed from these processes.

It should be understood that although the description herein is based on various embodiments, it is by no means the case that each embodiment contains just one independent technical solution. Such a method of presentation is adopted herein purely for the sake of clarity. Those skilled in the art should consider the description in its entirety. The technical solutions in the various embodiments could also be suitably combined to form other embodiments understandable to those skilled in the art.

The embodiments above are merely particular schematic embodiments of the present disclosure, which are not intended to limit the scope thereof. All equivalent changes, amendments and combinations made by any person skilled in the art without departing from the concept and principles shall fall within the scope of protection thereof.

What is claimed is:

1. A health condition assessment method for a medium/low voltage switchgear, having connection points between components of the medium/low voltage switchgear being provided with temperature sensors, and a main conduction circuit within the components, wherein the assessment method comprises:
determining key connection points in the main conduction circuit to serve as virtual temperature measurement points according to a main conduction circuit structure the medium/low voltage switchgear;
establishing a temperature analysis model of the main conduction circuit according to the distribution of the virtual temperature measurement points;
obtaining a current value, an environment temperature value, and temperature values of the main conduction circuit sensed by the temperature sensors, and putting the current value, the environment temperature value, and the temperature values into the temperature analysis model, to obtain temperature values or temperature-rise values of the virtual temperature measurement points in the main conduction circuit; and
obtaining temperature limit values or temperature-rise limit values of the virtual temperature measurement points in the main conduction circuit, using the temperature limit values or temperature-rise limit values to normalize the temperature values or temperature-rise values, and assessing the health condition of the medium/low voltage switchgear according to the normalized temperature values or temperature-rise values.

2. The assessment method as claimed in claim 1, wherein assessing the health condition of the medium/low voltage switchgear comprises: defining multiple health risk levels, and assessing the health condition of the medium/low voltage switchgear according to the normalized temperature values or temperature-rise values and the multiple health risk levels.

3. The assessment method as claimed in claim 2, wherein the method further comprises:
displaying a normalized temperature curve formed by the temperature value or temperature-rise value of each virtual temperature measurement point after normalization; and
displaying a level line of each of the multiple health risk levels.

4. The assessment method as claimed in claim 1, wherein establishing a temperature analysis model of the main conduction circuit comprises establishing a heat analysis model of the main conduction circuit based on equivalent parameters according to the number and positions of the virtual temperature measurement points.

5. The assessment method as claimed in claim 1, wherein obtaining the temperature limit values or temperature-rise limit values comprises:
determining the type of the medium/low voltage switchgear; and
determining the temperature limit values or temperature-rise limit values of the virtual temperature measurement points in the main conduction circuit according to the type of the medium/low voltage switchgear.

6. A health condition assessment apparatus for a medium/low voltage switchgear having temperature sensors at connection points between components of the medium/low voltage switchgear and a main conduction circuit within the components, the assessment apparatus comprising:
a determination module to determine key connection points in the main conduction circuit to serve as virtual temperature measurement points according to a main conduction circuit structure of the medium/low voltage switchgear;
a modelling module to establish a temperature analysis model of the main conduction circuit according to the distribution of the virtual temperature measurement points;
an application module to obtain a current value, an environment temperature value, and temperature values of the main conduction circuit from the temperature sensors, and put the current value, the environment temperature value, and the temperature values into the temperature analysis model, to obtain temperature values temperature-rise values of the virtual temperature measurement points in the main conduction circuit; and
an assessment module to obtain temperature limit values or temperature-rise limit values of the virtual temperature measurement points in the main conduction circuit, uses the temperature limit values or temperature-rise limit values to normalize the temperature values or temperature-rise values, and assesses the health condition of the medium/low voltage switchgear according to the normalized temperature values or temperature-rise values.

7. The assessment apparatus as claimed in claim 6, wherein assessing the health condition of the medium/low voltage switchgear according to the normalized temperature values or temperature-rise values comprises:
defining multiple health risk levels; and
assessing the health condition of the medium/low voltage switchgear according to: the normalized temperature values or temperature-rise values, and the multiple health risk levels.

8. The assessment apparatus as claimed in claim 7, further comprising module displaying a normalized temperature curve formed by the temperature value or temperature-rise value of each virtual temperature measurement point after normalization, and displaying a level line of each of the multiple health risk levels.

9. The assessment apparatus as claimed in claim 6, wherein establishing a temperature analysis model of the main conduction circuit according to the distribution of the virtual temperature measurement points comprises: establishing a heat analysis model of the main conduction circuit, based on equivalent parameters according to the number and positions of the virtual temperature measurement points.

10. The assessment apparatus as claimed in claim 6, wherein obtaining the temperature limit values or temperature-rise limit values of the virtual temperature measurement points in the main conduction circuit comprises:
determining the type of the medium/low voltage switchgear and
determining the temperature limit values or temperature-rise limit values of the virtual temperature measurement points in the main conduction circuit according to the type of the medium/low voltage switchgear.

11-13. (canceled)
